(19) United States
(12) Patent Application Publication
(10) Pub. No.: US 2024/0222125 A1
(43) Pub. Date: Jul. 4, 2024

(54) SiC EPITAXIAL WAFER AND METHOD FOR MANUFACTURING THE SAME

(71) Applicant: Resonac Corporation, Tokyo (JP)

(72) Inventor: Yoshikazu Umeta, Tokyo (JP)

(73) Assignee: Resonac Corporation, Tokyo (JP)

(21) Appl. No.: 18/396,087

(22) Filed: Dec. 26, 2023

(30) Foreign Application Priority Data
Dec. 28, 2022 (JP) 2022-211232

(51) Int. Cl. H01L 21/20; H01L 21/02; H01L 21/322; H01L 21/67; H01L 21/687

(52) U.S. Cl. CPC H01L 21/2015; H01L 21/02378; H01L 21/3225; H01L 21/67115; H01L 21/68714

(57) ABSTRACT

This SiC epitaxial wafer includes a SiC epitaxial layer on a surface thereof, wherein results of irradiating the SiC epitaxial wafer with excitation light having a wavelength of 313 nm and measuring an emission intensity of photoluminescence light having a wavelength of 660 nm or more for each square measurement region of 2 mm on a side, which is obtained by dividing the surface, satisfy the following formula (1).

{(I_{MAX}−Iₘᵢₙ)/I_{average}}×100≤40(%) (1)
(I_{MAX}: a maximum value of the emission intensity in the entire measurement region, Iₘᵢₙ: a minimum value of the emission intensity in the entire measurement region, and I_{average}: an average value of the emission intensity of the entire measurement region)

### BACKGROUND OF THE INVENTION

### Field of the Invention

The present disclosure relates to a SiC epitaxial wafer and a method for manufacturing a SiC epitaxial wafer.

Priority is claimed on Japanese Patent Application No. 2022-211232, filed Dec. 28, 2022, the content of which is incorporated herein by reference.

### Description of Related Art

Silicon carbide (SiC) has a dielectric breakdown field one order of magnitude larger and a bandgap three times larger than silicon (Si). In addition, silicon carbide (SiC) has a thermal conductivity about three times higher than that of silicon (Si). For these reasons, SiC epitaxial wafers have come to be used for semiconductor devices such as power devices, high frequency devices, and high temperature operation devices.

A SiC epitaxial wafer is manufactured by stacking a SiC epitaxial layer on the surface of a SiC single crystal substrate. Hereinafter, a substrate before a SiC epitaxial layer is stacked thereon will be referred to as a SiC single crystal substrate. Further, a substrate after a SiC epitaxial layer is stacked on the surface of a SiC single crystal substrate is referred to as a SiC epitaxial wafer.

Currently, the mainstream SiC single crystal substrate in the market is 6 inches (150 mm) in diameter. Development for mass production of SiC single crystal substrates with a diameter of 8 inches (200 mm) is progressing, and full-scale mass production is about to begin. Increasing the diameter of SiC single crystal substrates from 6 inches to 8 inches is expected to be a key for improving production efficiency and reducing costs.

In the related art, as a method for evaluating a SiC single crystal substrate, there is a method using photoluminescence (PL) measurement.

For example, Patent Document 1 describes a SiC single crystal that exhibits a PL spectrum with a near-infrared PL emission peak in a wavelength of 650 to 750 nm upon electronic excitation, and describes that a dislocation density is evaluated by PL imaging.

Further, Patent Document 2 describes a method for evaluating a SiC substrate in which a first surface of the SiC substrate cut out from a SiC ingot is irradiated with excitation light before an epitaxial film is stacked thereon and photoluminescence is measured. Further, Patent document 2 describes a SiC epitaxial wafer in which on the first surface of the SiC substrate, a region where the intensity of photoluminescence caused by impurities is stronger than the intensity of photoluminescence caused by a SiC band edge is 50% or less of the total area of the first surface.

Further, Patent Document 3 describes a silicon carbide single crystal substrate in which a first main surface and a second main surface are provided, the maximum diameter of the first main surface is 100 mm or more, the first main surface includes a first central region excluding a region within 3 mm from the outer circumference, and in a case where the first central region is divided into first square regions of 250 μm on a side, an oxygen concentration in the first square region is 5 atomic % or more and less than 20 atomic %.

In addition, Patent Document 4 describes a silicon carbide single crystal substrate with a diameter of 100 mm or more, an oxygen concentration of 1×10¹⁷ cm⁻³ or less, a dislocation density of 2×10⁴ cm⁻² or less, and an area ratio of stacking faults of 2.0% or less.

### PATENT DOCUMENTS

[Patent Document 1] Japanese Unexamined Patent Application, First Publication No. 2021-88469
[Patent Document 2] Japanese Unexamined Patent Application, First Publication No. 2020-40853
[Patent Document 3] Japanese Patent No. 5839069
[Patent Document 4] Japanese Unexamined Patent Application, First Publication No. 2017-7937

### SUMMARY OF THE INVENTION

However, it was found that in the SiC epitaxial wafer of the related art, there is a region where no defects are present even though the photoluminescence (PL) light emitted by irradiation with excitation light has a high emission intensity. In particular, it was found that the emission intensity in a portion near the outer circumference of the SiC epitaxial wafer is higher than in other portions. That is, it was found that even in a defect-free SiC epitaxial wafer, the emission intensity of the PL light is not uniform, and there is a region where the emission intensity of the PL light is high and a region where the emission intensity of the PL light is low.

As a result, in the technology of the related art, when evaluating a SiC epitaxial wafer using a difference in emission intensity of the PL light from the SiC epitaxial layer of the SiC epitaxial wafer, it was difficult to check for the presence or absence of defects due to PL light from a defect-free region, and thus it was not possible to obtain sufficient evaluation accuracy.

Further, in a region where the emission intensity of the PL light is high even though no defects are present, an energy level that should inherently not be present is present. Therefore, in a device using a SiC epitaxial wafer in which a SiC epitaxial layer is stacked in a region where the emission intensity of the PL light is high even though no defects are present, carriers are annihilated in a location that is not an inherently intended portion. For this reason, the influence on device operation due to a decrease in carrier lifetime has become a problem.

The present disclosure has been made in view of the above circumstances, and an object of the present disclosure is to provide a SiC epitaxial wafer in which the emission intensity of photoluminescence (PL) light from a SiC epitaxial layer which is emitted by irradiation with excitation light is uniform, and a method for manufacturing the SiC epitaxial wafer.

In order to solve the above problems, the present inventors focused their attention on a manufacturing apparatus for a SiC epitaxial wafer and diligently investigated as shown below.

A member made of quartz is used in the manufacturing apparatus for a SiC epitaxial wafer. This is because quartz is a material with good gas barrier properties, heat insulation properties, and corrosion resistance, and does not contain elements that can become dopants for SiC, such as boron (B), nitrogen (N), and aluminum (Al). Moreover, quartz is not expensive and is highly versatile.

The member made of quartz is installed, for example, to cover the surface of a metal member. This is because if the metal member is exposed, power efficiency is reduced, or the metal member corrodes and metal powder is generated, which causes contamination of the SiC epitaxial wafer and defects originating from the contamination.

Further, in an apparatus for manufacturing a SiC epitaxial wafer having a diameter of 150 mm (6 inches) or more, it is desirable to use a member made of quartz. Particularly, in an apparatus for manufacturing a SiC epitaxial wafer having a diameter of 200 mm (8 inches) or more, a member made of quartz is often used. This is because when manufacturing a SiC epitaxial wafer with a large diameter, the same level of quality cannot be obtained even using a manufacturing apparatus optimized for manufacturing a SiC epitaxial wafer with a current diameter, and the larger the diameter of the SiC epitaxial wafer, the greater the influence of contamination.

The present inventors focused their attention on a member made of quartz used in the manufacturing apparatus and diligently investigated the cause of the formation of regions where defects are not present, even though these regions have high emission intensity of PL light due to the irradiation with excitation light. As a result, it was found that the above cause was due to the desorption of water molecules contained in quartz from a member made of quartz when growing a SiC epitaxial layer.

Then, the present inventors subjected a member made of quartz to vacuum heat treatment under predetermined conditions to remove water molecules contained in the quartz, and then installed the member in a manufacturing apparatus. Then, using this manufacturing apparatus, a SiC epitaxial layer was stacked on the surface of the SiC single crystal substrate to manufacture a SiC epitaxial wafer. As a result, it was confirmed that a SiC epitaxial wafer in which the emission intensity of the PL light having a wavelength of 660 nm or more from the SiC epitaxial layer emitted by irradiating the SiC epitaxial wafer with excitation light having a wavelength of 313 nm is uniform can be obtained, and the present disclosure was conceived.

That is, the present disclosure relates to the following matters.
[1] A SiC epitaxial wafer including a SiC epitaxial layer on a surface thereof, wherein results of irradiating the SiC epitaxial wafer with excitation light having a wavelength of 313 nm and measuring an emission intensity of photoluminescence light having a wavelength of 660 nm or more for each square measurement region of 2 mm on a side, which is obtained by dividing the surface, satisfy the following formula (1).

{(I_{MAX}−Iₘᵢₙ)/I_{average}}×100≤40(%) (1)

(In formula (1), I_{MAX} is a maximum value of the emission intensity in the entire measurement region, Iₘᵢₙ is a minimum value of the emission intensity in the entire measurement region, and I_{average} is an average value of the emission intensity of the entire measurement region.)
[2] The SiC epitaxial wafer according to [1], wherein a nitrogen concentration on the surface is 4×10¹⁸ atoms/cm³ or less.
[3] The SiC epitaxial wafer according to [1] or [2], wherein an aluminum concentration on the surface is 4×10¹⁸ atoms/cm³ or less.
[4] The SiC epitaxial wafer according to any one of [1] to [3], wherein an oxygen concentration on the surface is less than 1×10¹⁴ atoms/cm³.
[5] The SiC epitaxial wafer according to any one of [1] to [4], wherein a triangular defect density on the surface is 1 cm⁻² or less.
[6] The SiC epitaxial wafer according to any one of [1] to [5], wherein the results of measuring the emission intensity of the photoluminescence light for each measurement region satisfy the following formula (2).

{(I_{MAX}−Iₘᵢₙ)/I_{average}}×100≤20(%) (2)

(In formula (2), I_{MAX} is a maximum value of the emission intensity in the entire measurement region, Iₘᵢₙ is a minimum value of the emission intensity in the entire measurement region, and I_{average} is an average value of the emission intensity of the entire measurement region.)
[7] The SiC epitaxial wafer according to any one of [1] to [6], wherein the results of measuring the emission intensity of the photoluminescence light for each measurement region satisfies the following formula (3).

{I_{o-average}/I_{average}}×100≤200(%) (3)

(In formula (3), I_{o-average} is an average value of the emission intensities of the measurement regions located at a portion closest to an outer circumference of the SiC epitaxial wafer among the measurement regions, and I_{average} is an average value of the emission intensity of the entire measurement region.)
[8] The SiC epitaxial wafer according to any one of [1] to [7], having a diameter of 150 mm (6 inches) or more.
[9] The SiC epitaxial wafer according to any one of [1] to [7], having a diameter of 200 mm (8 inches) or more.
[10] A method for manufacturing a SiC epitaxial wafer, comprising an epitaxial layer growth step of stacking a SiC epitaxial layer on a surface of a SiC single crystal substrate,
   wherein the epitaxial layer growth step is performed using an epitaxial apparatus including members made of quartz,
   wherein at least some of the members made of quartz are subjected to vacuum heat treatment before being installed in the epitaxial apparatus, and
   wherein, in the vacuum heat treatment, the members are held at a temperature of 600° C. or higher under a pressure of 1 kPa or lower for 1 hour or more.

In the SiC epitaxial wafer of the present disclosure, results of irradiating the SiC epitaxial wafer, which has the SiC epitaxial layer on the surface thereof, with the excitation light having a wavelength of 313 nm and measuring the emission intensity of the photoluminescence light having a wavelength of 660 nm or more for each square measurement region of 2 mm on a side, which is obtained by dividing the surface, satisfy formula (1). Therefore, in the SiC epitaxial wafer of the present disclosure, the emission intensity of photoluminescence (PL) light from a SiC epitaxial layer which is emitted by irradiation with excitation light is uniform. For this reason, in the SiC epitaxial wafer of the present disclosure, when evaluating the SiC epitaxial wafer using a difference in emission intensity of the PL light from the SiC epitaxial layer, it is possible to perform the evaluation with high accuracy. Further, in the SiC epitaxial wafer of the present disclosure, there is no region where the emission intensity of PL light is high even though there are no defects. Therefore, the device obtained by using the SiC epitaxial wafer of the present disclosure is preferable because a device operation is not affected by a decrease in carrier lifetime.

In the method for manufacturing a SiC epitaxial wafer of the present disclosure, the epitaxial layer growth step is performed using the epitaxial apparatus including the members made of quartz which have been subjected to the vacuum heat treatment before being installed in the epitaxial apparatus. Then, in the vacuum heat treatment, the members are held at a temperature of 600° C. or higher under a pressure of 1 kPa or lower for 1 hour or more. For this reason, according to the manufacturing method of the present disclosure, water molecules contained in quartz are not desorbed from a member made of quartz when growing a SiC epitaxial layer. As a result, the SiC epitaxial wafer of the present disclosure in which results of irradiating the SiC epitaxial wafer, which has the SiC epitaxial layer on the surface thereof, with the excitation light having a wavelength of 313 nm and measuring the emission intensity of the photoluminescence light having a wavelength of 660 nm or more for each square measurement region of 2 mm on a side, which is obtained by dividing the surface, satisfy formula (1) can be obtained.

### BRIEF DESCRIPTION OF THE DRAWINGS

FIG. 1A is a schematic cross-sectional view of a SiC epitaxial wafer according to an embodiment of the present disclosure.

FIG. 1B is a schematic plan view of the SiC epitaxial wafer according to the embodiment of the present disclosure.

FIG. 2 is a schematic cross-sectional view for explaining an example of an epitaxial apparatus that can be used when manufacturing the SiC epitaxial wafer according to the embodiment of the present disclosure.

FIG. 3 is a schematic cross-sectional view for explaining another example of the epitaxial apparatus that can be used when manufacturing the SiC epitaxial wafer according to the embodiment of the present disclosure.

FIG. 4 is a schematic cross-sectional view for explaining another example of the epitaxial apparatus that can be used when manufacturing the SiC epitaxial wafer according to the embodiment of the present disclosure.

FIG. 5 is a schematic cross-sectional view for explaining another example of the epitaxial apparatus that can be used when manufacturing the SiC epitaxial wafer according to the embodiment of the present disclosure.

FIG. 6 is a schematic cross-sectional view for explaining another example of the epitaxial apparatus that can be used when manufacturing the SiC epitaxial wafer according to the embodiment of the present disclosure.

FIG. 7 is a schematic cross-sectional view for explaining another example of the epitaxial apparatus that can be used when manufacturing the SiC epitaxial wafer according to the embodiment of the present disclosure.

FIG. 8 is a graph showing a relationship between a position (an X coordinate) from the center in a diametrical direction and an emission intensity of PL light (a PL intensity) of a SiC epitaxial wafer of each of Example 1 and Comparative Example 1.

### DETAILED DESCRIPTION OF THE INVENTION

Hereinafter, a SiC epitaxial wafer of the present disclosure will be explained in detail. The present disclosure is not limited only to embodiment which will be described below.

### [SiC Epitaxial Wafer]

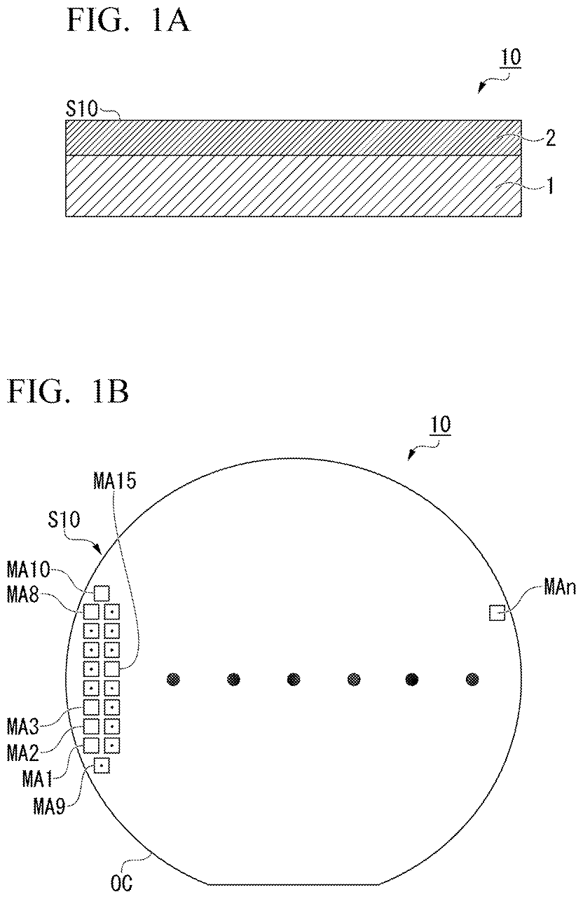

FIG. 1A is a schematic cross-sectional view of a SiC epitaxial wafer 10 according to an embodiment of the present disclosure, and FIG. 1B is a schematic plan view of the SiC epitaxial wafer 10 according to the embodiment of the present disclosure. The SiC epitaxial wafer 10 shown in FIGS. 1A and 1B includes a SiC single crystal substrate 1 and a SiC epitaxial layer 2 stacked on the SiC single crystal substrate 1. That is, the SiC epitaxial wafer 10 according to the present embodiment has the SiC epitaxial layer 2 on a surface S10. Results of irradiating the SiC epitaxial wafer 10 with excitation light having a wavelength of 313 nm and measuring an emission intensity of photoluminescence (PL) light having a wavelength of 660 nm or more for each of square measurement regions MA1 to MAn of 2 mm on a side, which is obtained by dividing the surface S10, satisfy the following formula (1). FIG. 1B shows some of the measurement regions MA1 to MAn of the SiC epitaxial wafer 10 as an example. With respect to some of the measurement regions MA1 to Man, a centered period symbol (⋅) is attached, and a symbol is indicated, or a reference sign is omitted.

{(I_{MAX}−Iₘᵢₙ)/I_{average}}×100≤40(%) (1)

(In formula (1), I_{MAX} is a maximum value of the emission intensity in the entire measurement region, Iₘᵢₙ is a minimum value of the emission intensity in the entire measurement region, and I_{average} is an average value of the emission intensity of the entire measurement region.)

The above formula (1) indicates the uniformity of the emission intensity of the PL light obtained from the entire measurement region. In the SiC epitaxial wafer of the present embodiment, the value of {(I_{MAX}−Iₘᵢₙ)/I_{average}}×100 is 40(%) or less, and thus the unevenness of the emission intensity of the PL light from the SiC epitaxial layer is sufficiently small and the emission intensity is uniform. In the SiC epitaxial wafer of the present embodiment, the value of {(I_{MAX}−Iₘᵢₙ)/I_{average}}×100 is preferably 20(%) or less, more preferably 10(%) or less, and the smaller the better.

In the SiC epitaxial wafer of the present embodiment, it is preferable that the results of measuring the emission intensity of the PL light described above for each measurement region satisfy the following formula (3).

{I_{o-average}/I_{average}}×100≤200(%) (3)

(In formula (3), I_{o-average} is an average value of the emission intensities of the measurement regions located at a portion closest to an outer circumference of the SiC epitaxial wafer among the measurement regions, and I_{average} is an average value of the emission intensity of the entire measurement region.)

The above formula (3) indicates that the emission intensity of the measurement region disposed at a portion closest to the outer circumference OC of the SiC epitaxial wafer is suppressed. In the example shown in FIG. 1B, among the measurement regions MA1 to MAn, the measurement regions located at a portion closest to the outer circumference are measurement regions MA1 to MA10, MAn, and the like, and the measurement regions such as the location indicated by the reference sign MA15, which are located further inside from the measurement regions MA1 to MA10 and MAn, are not the measurement regions located at a portion closest to the outer circumference OC. In a case where the SiC epitaxial wafer of the present embodiment satisfies formula (3), the emission intensity of a portion close to the outer circumference OC of the SiC epitaxial wafer, where the emission intensity of the PL light tends to be higher than other portions, is sufficiently suppressed. In the SiC epitaxial wafer of the present embodiment, the value of {I_{o-average}/I_{average}}×100 is more preferably 200(%) or less, more preferably 120(%) or less, and the smaller the better.

In the present embodiment, as a method in which the SiC epitaxial wafer 10 having the SiC epitaxial layer 2 on the surface S10 is irradiated with the excitation light having a wavelength of 313 nm and the emission intensity of the PL light having a wavelength of 660 nm or more is measured for each of the measurement regions MA1 to MAn, the apparatus and method known in the related art can be used.

A nitrogen concentration on the surface of the SiC epitaxial wafer 10 of the present embodiment is appropriately determined according to the tolerance and resistance standards of a semiconductor device in which the SiC epitaxial wafer is used. In the SiC epitaxial wafer of the present embodiment, the nitrogen concentration on the surface is preferably 4×10¹⁸ atoms/cm³ or less, more preferably 4×10¹⁷ atoms/cm³ or less, and further more preferably 4×10¹⁶ atoms/cm³ or less. When the nitrogen concentration on the surface is 4×10¹⁸ atoms/cm³ or less, it is easy to measure and inspect the concentration of the surface, and the resulting SiC epitaxial wafer can prevent breakdown voltage defects and on-resistance defects of the device, and thus which is preferable.

An aluminum concentration on the surface of the SiC epitaxial wafer of the present embodiment is appropriately determined according to the tolerance and resistance standards of a semiconductor device in which the SiC epitaxial wafer is used. In the SiC epitaxial wafer of the present embodiment, the aluminum concentration on the surface is preferably 4×10¹⁸ atoms/cm³ or less, more preferably 4×10¹⁷ atoms/cm³ or less, and further more preferably 4×10¹⁶ atoms/cm³ or less. When the aluminum concentration on the surface is 4×10¹⁸ atoms/cm³ or less, it is preferable because the measuring and inspecting of the concentration of the surface are easy and the resulting SiC epitaxial wafer can prevent breakdown voltage defects and on-resistance defects of the device.

In the SiC epitaxial wafer of the present embodiment, an oxygen concentration on the surface is preferably less than 1×10¹⁴ atoms/cm³. When the oxygen concentration on the surface is less than 1×10¹⁴ atoms/cm³, the emission intensity of the PL light having a wavelength of 660 nm or more which is emitted by irradiating the SiC epitaxial layer with the excitation light having a wavelength of 313 nm is not increased by the additional light emission due to the oxygen concentration on the surface. The oxygen concentration on the surface of the SiC epitaxial wafer is more preferably 1×10¹³ atoms/cm³ or less, and the lower the better.

In the SiC epitaxial wafer of the present embodiment, a triangular defect density on the surface is preferably 1 cm⁻² or less. A SiC epitaxial wafer having a triangular defect density on the surface of 1 cm⁻² or less has sufficiently few defects and is preferable as a wafer for semiconductor devices. The triangular defect density on the surface is more preferably 0.1 cm⁻² or less, and the smaller the better.

The size of the SiC epitaxial wafer of the present embodiment is not particularly limited, and may be 150 mm (6 inches) or more in diameter or may be 200 mm (8 inches) or more in diameter. In a case where the SiC epitaxial wafer of the present embodiment has a large diameter of 200 mm (8 inches) or more, it is preferable because semiconductor devices can be efficiently produced by using the SiC epitaxial wafer as a wafer for semiconductor devices.

### [Method for Manufacturing SiC Epitaxial Wafer]

The SiC epitaxial wafer of the present embodiment can be manufactured using, for example, a manufacturing method which will be described below.

First, the SiC single crystal substrate, which is a substrate before the SiC epitaxial layer is stacked thereon, is manufactured by a known method. Next, the SiC epitaxial layer is stacked on the surface of the SiC single crystal substrate to manufacture the SiC epitaxial wafer of the present embodiment.

In the present embodiment, as an apparatus (sometimes referred to as an “epitaxial apparatus”) for stacking the SiC epitaxial layer on the surface of the SiC single crystal substrate, an apparatus in which one or more members made of quartz are provided and some or all of the members made of quartz have been subjected to vacuum heat treatment before being installed is used. The vacuum heat treatment is preferably performed on all of the members made of quartz included in the epitaxial apparatus. The epitaxial apparatus may be any apparatus as long as it includes the members made of quartz, and may include a vertical furnace or may include a horizontal furnace.

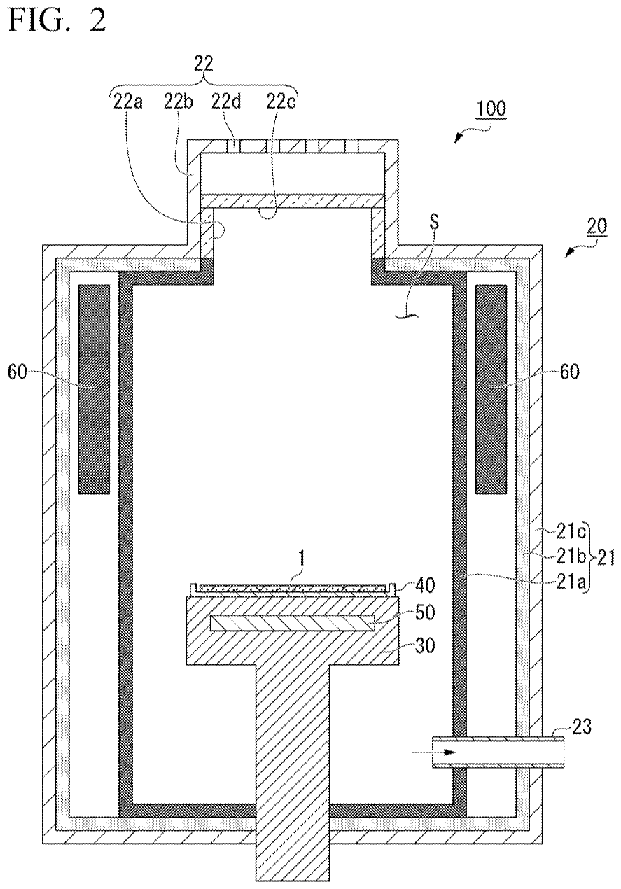

FIG. 2 is a schematic cross-sectional view for explaining an example of an epitaxial apparatus that can be used when manufacturing the SiC epitaxial wafer according to the present embodiment.

An epitaxial apparatus 100 shown in FIG. 2 includes a chamber 20, a support 30, a susceptor 40, a lower heater 50, and an upper heater 60. FIG. 2 shows a state in which the SiC single crystal substrate 1 is placed on the susceptor 40.

The chamber 20 has a main body 21 surrounding a film forming space S, a gas introduction part 22 for supplying a gas to the film forming space S, and a gas exhaust port 23 for exhausting a gas from the film forming space S.

The epitaxial apparatus 100 shown in FIG. 2 is a vertical furnace in which the gas introduction part 22 is disposed above a placement surface of the SiC single crystal substrate 1 placed in the film forming space S and the gas exhaust port 23 is disposed below the placement surface of the SiC single crystal substrate 1.

The main body 21 has a hollow, substantially cylindrical shape. As shown in FIG. 2, the wall surface of the main body 21 includes an inner layer 21a, a heat insulating layer 21b, and an outer layer 21c. The inner layer 21a is formed of, for example, isotropic graphite or the like. The heat insulating layer 21b is formed of, for example, carbon. The outer layer 21c is formed of, for example, a metal such as a stainless steel.

The gas introduction part 22 is provided at the center of the upper surface of the main body 21. The gas introduction part 22 has a hollow, substantially cylindrical shape that is concentric with the main body 21 and has a smaller diameter than the main body 21. As shown in FIG. 2, the gas introduction part 22 includes an inner wall member 22a that forms an inner wall surface of the gas introduction part 22, an outer wall member 22b that forms an outer wall surface of the gas introduction part 22, a rectifying plate 22c installed to cover the upper end of the inner wall member 22a, and a gas supply pipe 22d installed to cover the upper end of the outer wall member 22b. The gas supply pipe 22d supplies gases such as a source gas, a dopant gas, and a purge gas from the outside to the film forming space S in the main body 21 via the rectifying plate 22c. The rectifying plate 22c rectifies the gas supplied from the gas supply pipe 22d. The rectifying plate 22c is provided with a hole (not shown) having a predetermined shape at a predetermined position in a plan view.

In the epitaxial apparatus 100 shown in FIG. 2, the inner wall member 22a and the rectifying plate 22c of the gas introduction part 22 are made of quartz. The outer wall member 22b and the gas supply pipe 22d are formed of, for example, a metal such as stainless steel.

In the epitaxial apparatus 100 shown in FIG. 2, the case in which the inner wall member 22a and the rectifying plate 22c provided in the gas introduction part 22 are members made of quartz has been explained as an example, but it is sufficient if one or more of the members provided in the epitaxial apparatus 100 are made of quartz. The members made of quartz provided in the epitaxial apparatus 100 are preferably ones that form the gas introduction part 22, and in particular, the members such as the rectifying plate 22c and inner wall member 22a, which are directly exposed to the gases such as the source gas, the dopant gas, and the purge gas that reach the SiC single crystal substrate 1 and contribute to the growth of the SiC epitaxial layer, are preferably made of quartz. This is because it is possible to prevent defects from being formed in and contaminants from adhering to the SiC epitaxial layer formed on the surface of the SiC single crystal substrate 1.

In a case where the SiC epitaxial wafer is manufactured using the manufacturing method of the present embodiment, the epitaxial apparatus 100 in which at least some of the members made of quartz provided in the epitaxial apparatus 100 have been subjected to the vacuum heat treatment which will be described below before being installed is used. When at least some of the members made of quartz are subjected to the vacuum heat treatment before being installed in the epitaxial apparatus 100, the emission intensity of the PL light of the SiC epitaxial wafer manufactured using the epitaxial apparatus 100 becomes uniform, and the contamination of the SiC epitaxial layer can be effectively suppressed. The effect of the members made of quartz installed in the epitaxial apparatus 100, which have been subjected to the vacuum heat treatment before being installed, can be obtained more remarkably, and thus all of the members made of quartz provided in the epitaxial apparatus 100, are preferably subjected to the vacuum heat treatment before being installed.

In the present embodiment, the vacuum heat treatment of the members made of quartz, which are installed in the epitaxial apparatus 100, is performed using a vacuum heat treatment apparatus in a state where the members are removed from the epitaxial apparatus 100. This is because if at least some of the members made of quartz installed in the epitaxial apparatus 100 are subjected to the vacuum heat treatment in the epitaxial apparatus 100, the effect of the vacuum heat treatment may not be sufficiently obtained, or members made of other materials disposed around the members made of quartz may be adversely affected.

In the vacuum heat treatment of the members made of quartz, the members made of quartz are held at a temperature of 600° C. or higher under a pressure of 1 kPa or lower for one hour or more. As a result, water molecules contained in the members made of quartz can be sufficiently desorbed from the quartz and removed.

More specifically, since the temperature in the vacuum heat treatment is 600° C. or higher, the effect of desorbing the water molecules contained in the members made of quartz from the quartz can be obtained. The temperature in the vacuum heat treatment is preferably 800° C. or higher, and more preferably 900° C. or higher. When the temperature in the vacuum heat treatment is 800° C. or higher, the diffusion of the water molecules in the members made of quartz is promoted, and the water molecules are easily desorbed from the quartz. For this reason, when the temperature in the vacuum heat treatment is 800° C. or higher, the holding time in the vacuum heat treatment can be shortened, and the vacuum heat treatment can be performed efficiently. The temperature in the vacuum heat treatment is preferably 1300° C. or lower, and more preferably 1000° C. or lower to avoid devitrification or melting of the members made of quartz.

Further, since the pressure in the vacuum heat treatment is 1 kPa or lower, the effect of desorbing the water molecules contained in the members made of quartz from the quartz can be obtained. The pressure in the vacuum heat treatment is preferably 1×10⁻² Pa or lower, and more preferably 1×10⁻⁴ Pa or lower. This is because the effect of desorbing the water molecules contained in the members made of quartz from the quartz can be more effectively obtained through the vacuum heat treatment.

Further, since the holding time in the vacuum heat treatment is one hour or more, the effect of desorbing the water molecules contained in the members made of quartz from the quartz can be obtained. The holding time in the vacuum heat treatment is preferably two hours or more, and more preferably four hours or more. This is because the effect of desorbing the water molecules contained in the members made of quartz from the quartz can be more effectively obtained through the vacuum heat treatment. The holding time in the vacuum heat treatment is preferably 100 hours or less, and more preferably 50 hours or less. This is because the vacuum heat treatment can be performed in a short time and thus productivity is improved.

The vacuum heat treatment of the members made of quartz in the present embodiment only needs to be performed once before manufacturing the SiC epitaxial wafer using the epitaxial apparatus 100 including the members made of quartz. This is because even if moisture may adhere to the outermost surface of the members made of quartz after manufacturing the SiC epitaxial wafer and before manufacturing the SiC epitaxial wafer again, the moisture is extremely small compared to the amount of the water molecules incorporated into the members made of quartz in the process of manufacturing the members made of quartz. The vacuum heat treatment of the members made of quartz in the present embodiment may be performed every time or intermittently before manufacturing the SiC epitaxial wafer using the epitaxial apparatus 100 including the members made of quartz.

The members made of quartz which have been subjected to the vacuum heat treatment are installed at a predetermined location in the epitaxial apparatus 100 by a known method.

The support 30 provided in the epitaxial apparatus 100 shown in FIG. 2 supports the SiC single crystal substrate 1. The support 30 is rotatable about an axis. For example, the SiC single crystal substrate 1 is placed on the support 30 with placed on the susceptor 40.

The susceptor 40 is transported into the chamber 20 with the SiC single crystal substrate 1 placed thereon.

The lower heater 50 is installed within the support 30. The lower heater 50 heats the SiC single crystal substrate 1 via the support 30.

The upper heater 60 heats the upper portion of the chamber 20 from outside the chamber 20.

In the present embodiment, as a method for stacking the SiC epitaxial layer on the surface of the SiC single crystal substrate 1, a method known in the related art can be used except that the epitaxial apparatus 100 in which some or all of the members made of quartz have been subjected to the above-mentioned vacuum heat treatment is used.

Hereinafter, as an example of the method for manufacturing the SiC epitaxial wafer of the present embodiment, a method of stacking the SiC epitaxial layer on the surface of the SiC single crystal substrate 1 using the epitaxial apparatus 100 shown in FIG. 2 will be described as an example.

First, as shown in FIG. 2, the SiC single crystal substrate 1 is placed on the susceptor 40 and transported to the film forming space S in the chamber 20. After that, the SiC epitaxial layer is formed on the SiC single crystal substrate 1.

As a method for forming the SiC epitaxial layer, for example, a method in which the SiC single crystal substrate 1 is heated to 1550° C. or higher by the lower heater 50 and the upper heater 60 and a gas at 1550° C. to 1700° C. is supplied to the film forming space S above the SiC single crystal substrate 1 from the gas introduction part 22 can be used.

Examples of gases used for forming the SiC epitaxial layer include a source gas, a dopant gas, and a purge gas. As the source gas, Si source gas and C source gas are used. The Si source gas, the C source gas, the dopant gas, and the purge gas may be supplied independently, or some or all of them may be mixed and supplied.

The Si source gas is a gas containing Si in its molecules. For example, monosilane (SiH₄) can be used as the Si source gas. As the Si source gas, a chlorine-based Si material-containing gas (a chloride-based source gas) having an etching action, such as dichlorosilane (SiH₂Cl₂), trichlorosilane (SiHCl₃), or tetrachlorosilane (SiCl₄), may be used. Furthermore, hydrogen chloride gas may be added to the Si source gas.

As the C source gas, for example, propane (C₃H₈), ethylene (C₂H₄), or the like can be used.

The dopant gas is a gas containing an element that serves as a carrier in the SiC epitaxial layer, and controls the conductivity of the SiC epitaxial layer stacked on the SiC single crystal substrate 1. As the dopant gas, for example, nitrogen or the like can be used in a case where the conductivity type is n-type. As the dopant gas, TMA (trimethylaluminum) or the like can be used in a case where the conductivity type is p-type.

The purge gas is a gas for transporting the source gas and the dopant gas to the surface of the SiC single crystal substrate 1. As the purge gas, for example, hydrogen that is inert to SiC can be used. The flow rate of the purge gas is preferably 20 times or more the flow rate of the C source gas.

Through the above steps, the SiC epitaxial wafer of the present embodiment can be obtained.

In the SiC epitaxial wafer of the present embodiment, results of irradiating the SiC epitaxial wafer, which has the SiC epitaxial layer on the surface thereof, with the excitation light having a wavelength of 313 nm and measuring the emission intensity of the PL light having a wavelength of 660 nm or more for each square measurement region of 2 mm on a side, which is obtained by dividing the surface, satisfy formula (1). Therefore, the emission intensity of the PL light from the SiC epitaxial layer that emits light upon irradiation with the excitation light is uniform. For this reason, in the SiC epitaxial wafer of the present embodiment, when evaluating the SiC epitaxial wafer using a difference in emission intensity of the PL light from the SiC epitaxial layer, it is possible to perform the evaluation with high accuracy. Further, in the SiC epitaxial wafer of the present embodiment, there is no region where the emission intensity of PL light is high even though there are no defects. Therefore, the semiconductor device obtained by using the SiC epitaxial wafer of the present embodiment is preferable because a device operation is not affected by a decrease in carrier lifetime.

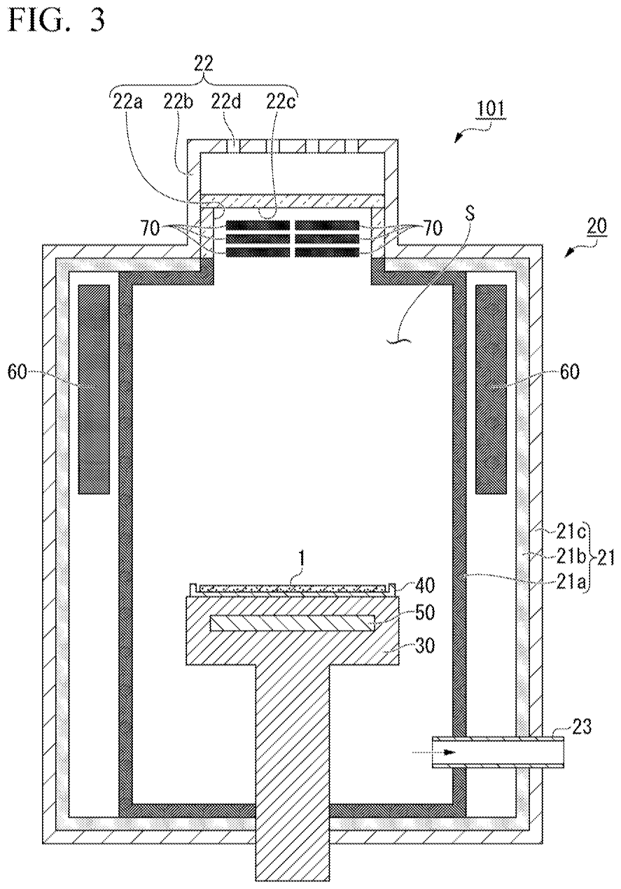

In the embodiment described above, the method for stacking the SiC epitaxial layer on the surface of the SiC single crystal substrate 1 using the epitaxial apparatus 100 shown in FIG. 2 has been explained as an example, but the SiC epitaxial layer may be stacked on the surface of the SiC single crystal substrate 1 using an epitaxial apparatus 101 shown in FIG. 3.

FIG. 3 is a schematic cross-sectional view for explaining another example of the epitaxial apparatus that can be used when manufacturing the SiC epitaxial wafer according to the present embodiment. In the epitaxial apparatus 101 shown in FIG. 3, the same members as those of the epitaxial apparatus 100 shown in FIG. 2 are designated by the same reference signs, and the description thereof will be omitted. The difference between the epitaxial apparatus 101 shown in FIG. 3 and the epitaxial apparatus 100 shown in FIG. 2 is that in the epitaxial apparatus 101 shown in FIG. 3, a plurality of (three in FIG. 3) heat shield plates 70 are installed between the gas introduction part 22 and the placement surface of the SiC single crystal substrate 1.

The heat shield plate 70 reflects radiation from an upper heater 60 in a film forming space S, and thermally shields the inner wall member 22a and the rectifying plate 22c provided in the gas introduction part 22. The heat shield plate 70 includes, for example, a plate member made of carbon and a SiC layer or TaC layer covering the surface of the plate member.

As shown in FIG. 3, the shape of the heat shield plate 70 can be a plate shape which is approximately circular in a plan view with a hole in the center. The shape of the heat shield plate 70 is not particularly limited as long as it does not adversely affect the supply condition of the gas supplied to the SiC single crystal substrate 1 from the gas introduction part 22. Further, the number of heat shield plates 70 is not particularly limited, and is appropriately determined according to the sizes of the heat shield plate 70 and the SiC single crystal substrate 1, the thickness and the material of the heat shield plate 70, and the like.

As a method for stacking the SiC epitaxial layer on the surface of the SiC single crystal substrate 1 using the epitaxial apparatus 101 shown in FIG. 3, a method similar to that when using the epitaxial apparatus 100 shown in FIG. 2 can be used.

In a case where the SiC epitaxial layer is stacked on the surface of the SiC single crystal substrate 1 using the epitaxial apparatus 101 shown in FIG. 3, the heat shield plate 70 suppresses the temperature rise of the inner wall member 22a and the rectifying plate 22c provided in the gas introduction part 22. For this reason, the SiC epitaxial wafer with more uniform emission intensity of the PL light having a wavelength of 660 nm or more from the SiC epitaxial layer emitted by irradiating the SiC epitaxial wafer with the excitation light having a wavelength of 313 nm can be obtained. This is presumed to be because the temperature rise of the members made of quartz which have been subjected to the vacuum heat treatment (the inner wall member 22a and the rectifying plate 22c in FIG. 3) is suppressed, and thus even if water molecules remain in the members made of quartz which have been subjected to the vacuum heat treatment, the desorption of the water molecules from the members made of quartz is suppressed when the SiC epitaxial layer is grown.

In the embodiment described above, although the case in which the epitaxial apparatuses 100 and 101 shown in FIGS. 2 and 3 each including a vertical furnace are used as the epitaxial apparatus has been explained as an example, the present disclosure is not limited to the embodiment using the epitaxial apparatuses. The epitaxial apparatus which is used in the present disclosure may be any apparatus as long as it includes the members made of quartz, and may include a horizontal furnace.

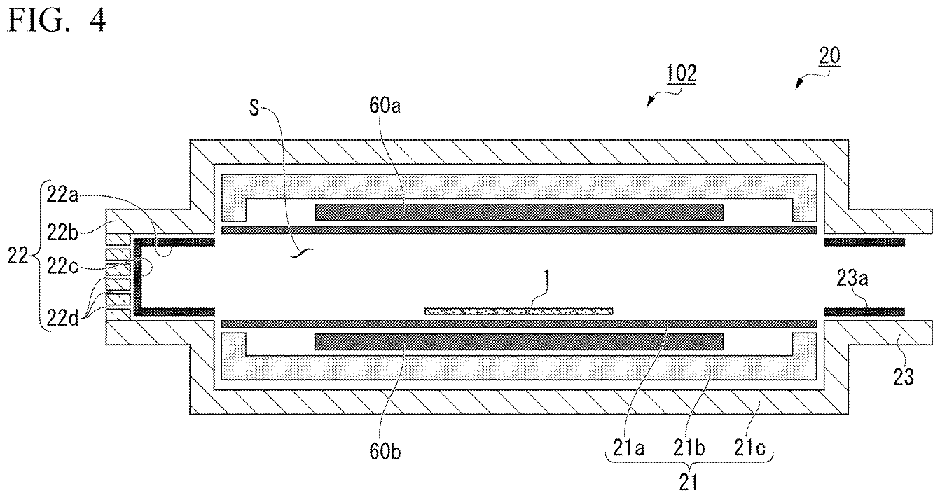

As the epitaxial apparatus that includes the horizontal furnace, for example, the following can be used. Each of FIGS. 4 to 7 is a schematic cross-sectional view for explaining another example of the epitaxial apparatus that can be used when manufacturing the SiC epitaxial wafer according to the present embodiment. In epitaxial apparatuses 102, 103, 104, and 105 shown in FIGS. 4 to 7, the same members as those of the epitaxial apparatus 100 shown in FIG. 2 are designated by the same reference signs, and the description thereof will be omitted.

In the epitaxial apparatuses 102, 103, 104, and 105 shown in FIGS. 4 to 7, unlike the epitaxial apparatus 100 shown in FIG. 2, the gas introduction part 22 and the gas exhaust port 23 are disposed on opposite sides of the chamber 20. Furthermore, in the epitaxial apparatuses 102, 103, 104, and 105 shown in FIGS. 4 to 7, unlike the epitaxial apparatus 100 shown in FIG. 2, an inner layer 23a which is a member made of quartz is provided on the inner wall of the gas exhaust port 23. In the epitaxial apparatuses 102, 103, 104, and 105 shown in FIGS. 4 to 7, the SiC single crystal substrate 1 is placed on the inner layer 21a forming the lower surface of the film forming space S.

In the epitaxial apparatus 102 shown in FIG. 4, an upper heater 60a is installed between the inner layer 21a, which constitutes the upper surface of the film forming space S and the heat insulating layer 21b, and a lower heater 60b is installed between the inner layer 21a, which constitutes the lower surface of the film forming space S and the heat insulating layer 21b. The inner wall member 22a, the rectifying plate 22c, and the inner layer 23a in the epitaxial apparatus 102 shown in FIG. 4 are members made of quartz which have been subjected to the vacuum heat treatment.

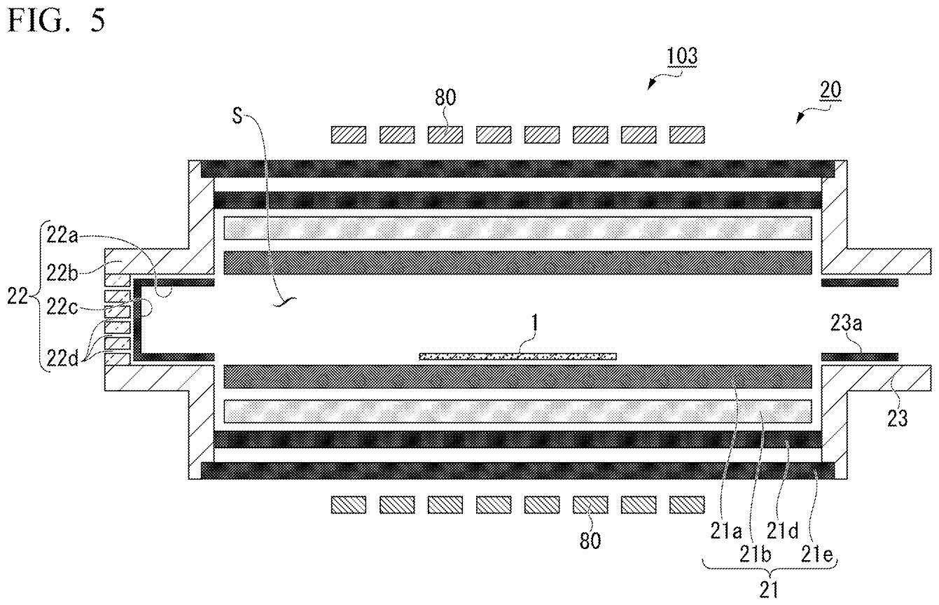

The epitaxial apparatus 103 shown in FIG. 5 differs from the epitaxial apparatus 102 shown in FIG. 4 in that the main body 21 has a structure in which, from the inside, the inner layer 21a, the heat insulating layer 21b, a first quartz layer 21d, and a second quartz layer 21e are stacked in that order, and that the epitaxial apparatus 103 does not have the upper heater 60a and the lower heater 60b but has a dielectric coil 80 installed on the outside of the main body 21. The inner wall member 22a, the rectifying plate 22c, the first quartz layer 21d, the second quartz layer 21e, and the inner layer 23a in the epitaxial apparatus 103 shown in FIG. 5 are members made of quartz which have been subjected to the vacuum heat treatment.

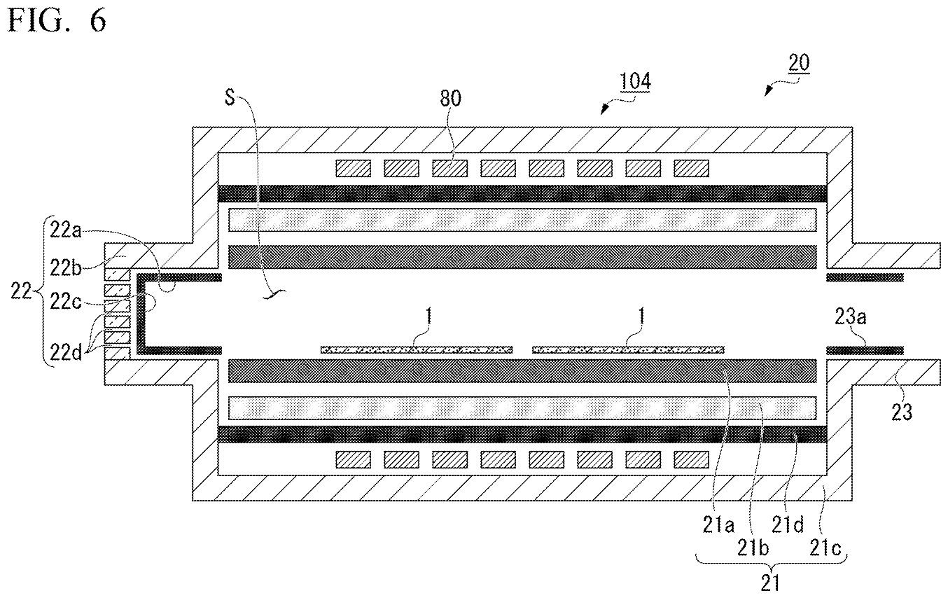

The epitaxial apparatus 104 shown in FIG. 6 differs from the epitaxial apparatus 102 shown in FIG. 4 in that the first quartz layer 21d is installed between the heat insulating layer 21b and the outer layer 21c, and that the epitaxial apparatus 104 does not have the upper heater 60a and the lower heater 60b but has a dielectric coil 80 installed between the first quartz layer 21d and the outer layer 21c. The inner wall member 22a, the rectifying plate 22c, the first quartz layer 21d, and the inner layer 23a in the epitaxial apparatus 104 shown in FIG. 6 are members made of quartz which have been subjected to the vacuum heat treatment. In the epitaxial apparatus 104 shown in FIG. 6, on a line connecting the gas introduction part 22 and the gas exhaust port 23 on the inner layer 21a forming the lower surface of the film forming space S, two SiC single crystal substrates 1 may be placed side by side as shown in FIG. 6, or only one SiC single crystal substrate 1 may be placed. In addition, in the epitaxial apparatus 104 shown in FIG. 6, three to eight SiC single crystal substrates 1 may be placed annularly at equal intervals on the inner layer 21a forming the lower surface of the film forming space S.

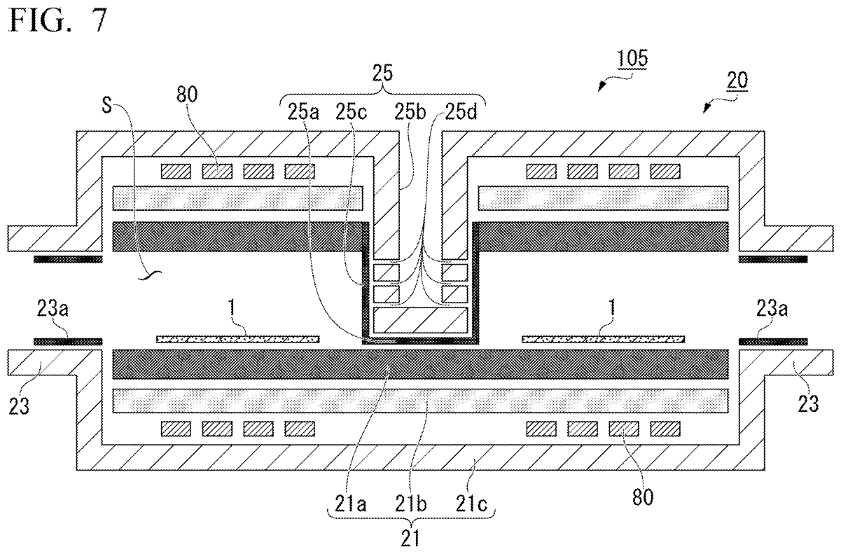

The epitaxial apparatus 105 shown in FIG. 7 differs from the epitaxial apparatus 102 shown in FIG. 4 mainly in two points. The first point is that a gas introduction part in the form of a concave portion which is approximately circular in a plan view is disposed at the center of the upper surface of the chamber 20 having an approximately cylindrical shape, that the gas exhaust ports 23 are disposed on the sides of the chamber opposite to two gas supply pipes 25d of the gas introduction part 25. The second point is that the epitaxial apparatus 105 does not have the upper heater 60a and the lower heater 60b but has a dielectric coil 80 installed between the heat insulating layer 21b and the outer layer 21c.

The gas introduction part 25 in the epitaxial apparatus 105 shown in FIG. 7 has an inner wall member 25a in a concave shape which is approximately circular in a plan view and forms a part of the inner wall of the chamber 20, and an outer wall member 25b in a concave shape which is approximately circular in a plan view, is disposed along the inside of the concave shape of the inner wall member 25a, and forms a part of the outer layer 21c of the chamber 20. Further, the gas introduction part 25 includes two rectifying plates 25c provided extending from the side surface of the inner wall member 25a, and two gas supply pipes 25d provided on the outer wall member 25b to be opposite to the two rectifying plates 25c. In the epitaxial apparatus 105 shown in FIG. 7, the inner wall member 22a, the rectifying plate 22c, and the inner layer 23a of the gas introduction part 22 are members made of quartz which have been subjected to the vacuum heat treatment. In the epitaxial apparatus 105 shown in FIG. 7, the SiC single crystal substrates 1 are placed on the respective lines connecting the two gas introduction parts 25 and the gas exhaust ports 23 on the inner layer 21a forming the lower surface of the film forming space S. In addition, in the epitaxial apparatus 105 shown in FIG. 7, three to eight SiC single crystal substrates 1 may be placed annularly at equal intervals on the inner layer 21a forming the lower surface of the film forming space S.

The epitaxial apparatuses 100, 101, 102, 103, 104, and 105 shown in FIGS. 2 to 7 have the members made of quartz which have been subjected to the vacuum heat treatment before being installed. Therefore, in a case where the SiC epitaxial layer is stacked on the surface of the SiC single crystal substrate 1 using any epitaxial apparatus selected from these epitaxial apparatuses 100, 101, 102, 103, 104, and 105, water molecules contained in the quartz are not desorbed from the member made of quartz. As a result, the SiC epitaxial wafer of the present embodiment in which results of irradiating the SiC epitaxial wafer, which has the SiC epitaxial layer on the surface thereof, with the excitation light having a wavelength of 313 nm and measuring the emission intensity of the photoluminescence light having a wavelength of 660 nm or more for each square measurement region of 2 mm on a side, which is obtained by dividing the surface, satisfy formula (1) can be obtained.

### EXAMPLES

Hereinafter, the present disclosure will be explained in more detail with reference to examples and a comparative example. The present disclosure is not limited only to the following examples.

### Example 1

A SiC single crystal substrate with a diameter of 6 inches was prepared. Next, using the epitaxial apparatus 100 shown in FIG. 2, a SiC epitaxial layer was stacked on the surface of the SiC single crystal substrate 1 to obtain a SiC epitaxial wafer of Example 1.

In the epitaxial apparatus 100 shown in FIG. 2, the inner wall member 22a and the rectifying plate 22c provided in the gas introduction part 22 are members made of quartz. The inner wall member 22a and the rectifying plate 22c were subjected to the vacuum heat treatment which will be described below before being installed in the epitaxial apparatus 100.

As the vacuum heat treatment, heat treatment in which the quartz member removed from the epitaxial apparatus 100 was held at 1000° C. for 48 hours under a pressure of 1×10⁻³ Pa or less using a vacuum heat treatment apparatus was performed.

The member made of quartz which had been subjected to the vacuum heat treatment was cooled to room temperature in the vacuum heat treatment apparatus, and then installed in the epitaxial apparatus 100 shown in FIG. 2.

Further, the SiC single crystal substrate 1 was placed on the susceptor 40 and transported to the film forming space S in the chamber 20 of the epitaxial apparatus 100 shown in FIG. 2. After that, the SiC epitaxial layer was formed on the SiC single crystal substrate 1.

For forming the SiC epitaxial layer, a method in which the SiC single crystal substrate 1 is heated to 1600° C. by the lower heater 50 and the upper heater 60, the Si source gas, the C source gas, the dopant gas, and the purge gas are supplied from the gas supply pipe 22d of the gas introduction part 22, and the gas at 1600° C. which has been passed through the rectifying plate 22c is supplied to the film forming space S above the SiC single crystal substrate 1 was used.

Through the above steps, the SiC epitaxial wafer of Example 1 which has a SiC epitaxial layer with a thickness of 350 μm on the surface of the SiC single crystal substrate 1 was obtained.

### Example 2

A SiC epitaxial wafer of Example 2 was obtained by the same method as that for the SiC epitaxial wafer of Example 1, except that the epitaxial apparatus 101 shown in FIG. 3 in which three heat shield plates 70 each of which is constituted by a plate member made of carbon and a SiC layer covering the surface of the plate member and has a plate shape which is approximately circular in a plan view with a hole in the center were installed was used instead of the epitaxial apparatus 100 shown in FIG. 2.

### Comparative Example 1

A SiC epitaxial wafer of Comparative Example 1 was obtained by the same method as that for the SiC epitaxial wafer of Example 1, except that the inner wall member 22a and the rectifying plate 22c were installed in the epitaxial apparatus 100 without being subjected to the vacuum heat treatment.

The SiC epitaxial wafers of Example 1, Example 2, and Comparative Example 1 obtained in such a way were irradiated with the excitation light, and the emission intensity of the PL light (the PL intensity) was measured for each square measurement region of 2 mm on a side, which is obtained by dividing the surface. The measurement conditions for the PL light will be shown below.

### [PL Light Measurement Conditions]

PL light measurement device: manufactured by Lasertec (product name: SICA88)
Measurement temperature: room temperature
Excitation wavelength: 313 nm
Measurement wavelength: Near infrared region (NIR region) of 660 nm or more

In addition, using the results of measuring the emission intensity of PL light for each measurement region, a value of {(I_{MAX}−Iₘᵢₙ)/I_{average}}×100(%) (in the formula, I_{MAX} is a maximum value of the emission intensity in the entire measurement region, Iₘᵢₙ is a minimum value of the emission intensity in the entire measurement region, and I_{average} is an average value of the emission intensity of the entire measurement region.) was calculated. The results are shown in Table 1.

In addition, using the results of measuring the emission intensity of PL light for each measurement region, a value of {I_{o-average}/I_{average}}×100(%) (in the formula, I_{o-average} is an average value of the emission intensities of the measurement regions located at a portion closest to an outer circumference of the SiC epitaxial wafer among the measurement regions, and I_{average} is an average value of the emission intensity of the entire measurement region.) was calculated. The results are shown in Table 1.

TABLE 1

| | {(I_{MAX} − Iₘᵢₙ)/[I_{average}} × 100 | {I_{0-average}/I_{average}} × 100 |
|---|---|---|
| | (%) | (%) |
| Example 1 | 8 | 105 |
| Example 2 | 8 | 94 |
| Comparative | 215 | 248 |
| Example 1 | | |

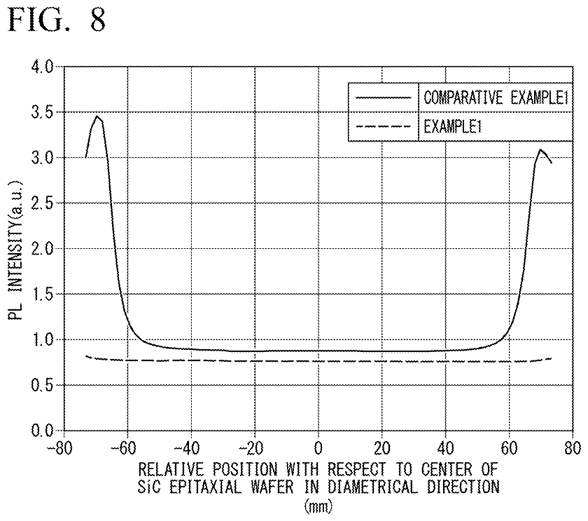

In addition, for Example 1 and Comparative Example 1, from the measurement results of the emission intensity of the PL light for each measurement region along the diameter of the SiC epitaxial wafer, a relationship between the position (the X coordinate) from the center in the diametrical direction of the SiC epitaxial wafer and the emission intensity of the PL light (the PL intensity) was investigated. The results are shown in FIG. 8. The center of the SiC epitaxial wafer described above is the center of a circle without taking into account the orientation flat or notch of the SiC epitaxial wafer.

As shown in Table 1, in Example 1 and Example 2, the value of {(I_{MAX}−Iₘᵢₙ)/I_{average}}×100, which indicates the uniformity of the emission intensity of the PL light obtained from the entire measurement region, was a very low compared to that in Comparative Example 1.

Further, in Example 1 and Example 2, the value of {I_{o-average}/I_{average}}×100, which indicates that the emission intensity of the measurement region located at a portion closest to the outer circumference of the SiC epitaxial wafer is suppressed, was very low compared to that in Comparative Example 1. In particular, in Example 2, the value of {I_{o-average}/I_{average}}×100 was low. This is presumed to be because in Example 2, the heat shield plate 70 suppressed the temperature rise of the inner wall member 22a and the rectifying plate 22c provided in the gas introduction part 22 when the SiC epitaxial layer is formed.

Further, as shown in FIG. 8, in Example 1, the emission intensity of the PL light was low compared to that in Comparative Example 1 at any position in the diametrical direction of the SiC epitaxial wafer.

Furthermore, in Comparative Example 1, the emission intensity of the measurement region located at a portion close to the outer circumference of the SiC epitaxial wafer is very high. In contrast, in Example 1, the emission intensity of the measurement region located at a portion close to the outer circumference of the SiC epitaxial wafer is suppressed.

In addition, the SiC epitaxial wafers of Example 1, Example 2, and Comparative Example 1 were analyzed using a secondary ion mass spectrometry (SIMS) device (manufactured by Cameca; Dynamic SIMS), and the oxygen concentration, the nitrogen concentration, and the aluminum concentration were obtained. The results are shown in Table 2.

In addition, the SiC epitaxial wafers of Example 1, Example 2, and Comparative Example 1 were observed using an optical microscope (manufactured by Lasertec; trade name: SICA88), and the focal position was shifted from the surface of the SiC epitaxial wafer toward the interface between the SiC epitaxial layer and the SiC single crystal substrate (in a depth direction of the SiC epitaxial layer), and thus the presence or absence of triangular defects originating from particulate deposits was confirmed, and the density thereof was obtained. The results are shown in Table 2.

TABLE 2

| | Oxygen | Nitrogen | Aluminum | Triangular |
|---|---|---|---|---|
| | concentration | concentration | concentration | defect density |
| | (atoms/cm³) | (atoms/cm³) | (atoms/cm³) | (cm⁻²) |
| Example 1 | less than | 2.9 × 10¹⁵ | less than | 0.04 |
| | 1 × 10¹⁵ | | 5 × 10¹³ | |
| Example 2 | less than | 1.5 × 10¹⁶ | less than | 0.00 |
| | 1 × 10¹⁵ | | 5 × 10¹³ | |
| Comparative | less than | 4.3 × 10¹⁵ | less than | 0.01 |
| Example 1 | 1 × 10¹⁵ | | 5 × 10¹³ | |

As shown in Table 2, in all of Example 1, Example 2, and Comparative Example 1, the oxygen concentration, the nitrogen concentration, and the aluminum concentration are sufficiently low.

The lower limit of detection of the oxygen concentration when analyzed using the secondary ion mass spectrometer (SIMS) device is 1×10¹⁵ atoms/cm³. For this reason, as shown in Table 2, it cannot be determined from the results of the above oxygen analysis whether or not the oxygen concentration on the surface of the SiC epitaxial wafer of each of Example 1, Example 2, and Comparative Example 1 is less than 1×10¹⁴ atoms/cm³.

However, as shown in Table 1, in the SiC epitaxial wafers of Example 1 and Example 2, the value of {(I_{MAX}−Iₘᵢₙ)/I_{average}}×100, which indicates the uniformity of the emission intensity of the PL light obtained from the entire measurement region, was a very low. From this, it can be presumed that the SiC epitaxial wafers of Example 1 and Example 2 have surface oxygen concentrations of less than 1×10¹⁴ atoms/cm³. This means that when the oxygen concentration on the surface of the SiC epitaxial wafer is more than 1×10¹⁴ atoms/cm³, the emission intensity of the PL light having a wavelength of 660 nm or more which is emitted by irradiating the SiC epitaxial wafer with the excitation light having a wavelength of 313 nm is increased by the additional light emission due to the oxygen concentration on the surface. As a result, the uniformity of the emission intensity of the PL light obtained from the entire measurement region becomes poor, and the value of {(I_{MAX}−Iₘᵢₙ)/I_{average}}×100 exceeds 40(%). Even if the emission intensity of the PL light is large over the entire in-plane region, if the in-plane distribution is uniform, by correcting the emission intensity by background removal processing, when evaluating the SiC epitaxial wafer using a difference in emission intensity of the PL light from the SiC epitaxial layer, it is possible to perform the evaluation with high accuracy.

Furthermore, in all of Example 1, Example 2, and Comparative Example 1, the triangular defect density is sufficiently low.

As described above, the preferable embodiments of the present disclosure have been described in detail, the present disclosure is not limited to specific embodiments, and various modifications and changes can be made within the scope of the gist of the present disclosure described in the claims.

While preferred embodiments of the invention have been described and illustrated above, it should be understood that these are exemplary of the invention and are not to be considered as limiting. Additions, omissions, substitutions, and other modifications can be made without departing from the spirit or scope of the present disclosure. Accordingly, the invention is not to be considered as being limited by the foregoing description, and is only limited by the scope of the appended claims.

### EXPLANATION OF REFERENCES

1 SiC single crystal substrate
2 SiC epitaxial layer
10 SiC epitaxial wafer
20 Chamber
21 Main body
21a Inner layer
21b Heat insulating layer
21c Outer layer
22 Gas introduction part
22a Inner wall member
22b Outer wall member
22c Rectifying plate
22d Gas supply pipe
23 Gas exhaust port
30 Support
40 Susceptor
50 Lower heater
60 Upper heater
70 Heat shield plate
100, 101, 102, 103, 104, 105 Epitaxial apparatus
S Film forming space
S10 Surface

What is claimed is:

1. A SiC epitaxial wafer comprising a SiC epitaxial layer on a surface thereof,
wherein results of irradiating the SiC epitaxial wafer with excitation light having a wavelength of 313 nm and measuring an emission intensity of photoluminescence light having a wavelength of 660 nm or more for each square measurement region of 2 mm on a side, which is obtained by dividing the surface, satisfy the following formula (1).
{(I_{MAX}−Iₘᵢₙ)/I_{average}}×100≤40(%) (1)
(In formula (1), I_{MAX} is a maximum value of the emission intensity in the entire measurement region, Iₘᵢₙ is a minimum value of the emission intensity in the entire measurement region, and I_{average} is an average value of the emission intensity of the entire measurement region.)

2. The SiC epitaxial wafer according to claim 1, wherein a nitrogen concentration on the surface is 4×10¹⁸ atoms/cm³ or less.

3. The SiC epitaxial wafer according to claim 1, wherein an aluminum concentration on the surface is 4×10¹⁸ atoms/cm³ or less.

4. The SiC epitaxial wafer according to claim 1, wherein an oxygen concentration on the surface is less than 1×10¹⁴ atoms/cm³.

5. The SiC epitaxial wafer according to claim 1, wherein a triangular defect density on the surface is 1 cm⁻² or less.

6. The SiC epitaxial wafer according to claim 1, wherein the results of measuring the emission intensity of the photoluminescence light for each measurement region satisfy the following formula (2).
{(I_{MAX}−Iₘᵢₙ)/I_{average}}×100≤20(%) (2)
(In formula (2), I_{MAX} is a maximum value of the emission intensity in the entire measurement region, Iₘᵢₙ is a minimum value of the emission intensity in the entire measurement region, and I_{average} is an average value of the emission intensity of the entire measurement region.)

7. The SiC epitaxial wafer according to claim 1, wherein the results of measuring the emission intensity of the photoluminescence light for each measurement region satisfy the following formula (3).
{I_{o-average}/I_{average}}×100≤200(%) (3)
(In formula (3), I_{o-average} is an average value of the emission intensities of the measurement regions located at a portion closest to an outer circumference of the SiC epitaxial wafer among the measurement regions, and I_{average} is an average value of the emission intensity of the entire measurement region.)

8. The SiC epitaxial wafer according to claim 1, having a diameter of 150 mm or more.

9. The SiC epitaxial wafer according to claim 1, having a diameter of 200 mm or more.

10. A method for manufacturing a SiC epitaxial wafer, comprising an epitaxial layer growth step of stacking a SiC epitaxial layer on a surface of a SiC single crystal substrate,
wherein the epitaxial layer growth step is performed using an epitaxial apparatus including members made of quartz,
wherein at least some of the members made of quartz are subjected to vacuum heat treatment before being installed in the epitaxial apparatus, and
wherein the vacuum heat treatment is heat treatment in which the members are held at a temperature of 600° C. or higher under a pressure of 1 kPa or lower for 1 hour or more.
